(19) United States
(12) Patent Application Publication
(10) Pub. No.: US 2024/0244828 A1
(43) Pub. Date: Jul. 18, 2024

(54) MEMORY STRUCTURE AND MANUFACTURING METHOD THEREOF

(71) Applicant: NANYA TECHNOLOGY CORPORATION, New Taipei city (TW)

(72) Inventor: Chun-Heng WU, Taoyuan City (TW)

(21) Appl. No.: 18/155,043

(22) Filed: Jan. 16, 2023

(51) Int. Cl. H10B 12/00

(52) U.S. Cl. CPC H10B 12/34; H10B 12/053; H10B 12/485

(57) ABSTRACT

A memory structure includes a semiconductor substrate, two word line structures, an isolation structure, and a bit line contact layer. The semiconductor substrate has a first trench, a second trench, a first top surface, and a second top surface adjoining the first and second trenches and lower than the first top surface. The two word line structures are respectively located in the first and second trenches. The isolation structure is located on the two word line structures and in contact with a sidewall of the first trench and a sidewall of the second trench, in which the isolation structure has a top surface extending to and coplanar with the second top surface of the semiconductor substrate. The bit line contact layer is located on the second top surface of the semiconductor substrate and surrounded by the isolation structure.

### BACKGROUND

### Field of Invention

The present disclosure relates to a memory structure and a manufacturing method of the memory structure.

### Description of Related Art

Random access memory (RAM) is a volatile memory, which is typically used for temporary storage of program data in a computer system and can be categorized into static RAM (SRAM) and dynamic RAM (DRAM). In SRAM, information is stored by the conductive state of the transistors in the memory cells, which does not need to be periodically rewritten and is maintained as power is provided to the memory chip. On the other hand, data in DRAM is determined by the charging states of capacitors in the memory cells, in which DRAM should be continually rewritten to keep the data. In general, information access in RAM is controlled by word lines having gates and bit lines connecting source and drain, in which the bit lines are contacted with the memory cells by bit line contact layers. In usual, a dry etching and cleaning process is applied to create a recess to form a bit line contact layer, and usually causes the oxide layer loss and creates voids in the traditional memory cell. Therefore, during the formation of the bit line contact layer, the voids are also filled by the bit line contact layer and induce a leakage issue. An additional dry etching and cleaning process has been applied to prevent the voids in the traditional memory cell. However, the additional dry etching and cleaning process may cause the opening holes of the trenches having the word lines expand and therefore limits the size of the RAMs fabricated through this process.

### SUMMARY

One aspect of the present disclosure provides a memory structure.

According to some embodiments of the present disclosure, a memory structure includes a semiconductor substrate, two word line structures, an isolation structure, and a bit line contact layer. The semiconductor substrate has a first trench, a second trench, a first top surface, and a second top surface between the first trench and the second trench, in which the second top surface is lower than the first top surface. One of the two line structures is located in a lower portion of the first trench, and the other word line structure is located in a lower portion of the second trench. The isolation structure is located in the first trench and the second trench and on the two word line structures. The isolation structure is in contact with a sidewall of the first trench, a sidewall of the second trench, and extends onto the first top surface of the semiconductor substrate, in which the isolation structure has a top surface extending to and coplanar with the second top surface of the semiconductor substrate. The bit line contact layer is located on the second top surface of the semiconductor substrate and surrounded by the isolation structure.

In some embodiments, the isolation structure is in contact with top surfaces of the two word line structures.

In some embodiments, the memory structure further includes a first isolation layer and a second isolation layer. The first isolation layer is on the first top surface of the semiconductor substrate. The second isolation layer is on the first isolation layer, in which each of the first isolation layer and the second isolation layer has an inner sidewall in contact with the isolation structure.

In some embodiments, the inner sidewall of the first isolation layer and the inner sidewall of the second isolation layer are perpendicular to the first top surface of the semiconductor substrate.

In some embodiments, the bit line contact layer has no portion between the second isolation layer and the isolation structure.

In some embodiments, the bit line contact layer has no portion below the second top surface of the semiconductor substrate.

In some embodiments, the bit line contact layer has a trapezoid profile in cross-section.

In some embodiments, each of the two word line structures further includes a lower gate electrode, an upper gate electrode, and a barrier layer. The upper gate electrode overlaps the lower gate electrode and has a top surface in contact with the isolation structure. The barrier layer surrounds the lower gate electrode and has a portion between the upper gate electrode and the lower gate electrode.

In some embodiments, a material of the lower gate electrode is different from a material of the upper gate electrode.

In some embodiments, the material of the lower gate electrode comprises tungsten, and the material of the upper gate electrode includes polysilicon.

In some embodiments, the material of the upper gate electrode is same as a material of the bit line contact layer.

In some embodiments, a material of the barrier layer includes titanium nitride.

In some embodiments, the memory structure further includes an outer oxide layer located between the upper gate electrode and the barrier layer, and extending to the isolation structure along a sidewall of the upper gate electrode.

In some embodiments, the memory structure further includes an inner oxide layer. The inner oxide layer is between the outer oxide layer and the sidewall of one of the first and second trenches, and between the barrier layer and the sidewall of one of the first and second trenches.

In some embodiments, the isolation structure has a first portion in the first trench and a second portion in the second trench, a width of the first portion is the same as a width of the first trench, and a width of the second portion is the same as a width of the second trench.

Another aspect of the present disclosure provides a manufacturing method of a memory structure.

According to some embodiments of the present disclosure, a manufacturing method of a memory structure includes forming a first trench and a second trench in a semiconductor substrate; forming two word line structures respectively in the first trench and the second trench; forming an isolation structure in the first trench and the second trench and on the two word line structures, wherein the isolation structure is in contact with a sidewall of the first trench and a sidewall of the second trench, and extends onto a first top surface of the semiconductor substrate; removing a portion of the isolation structure and a portion of the semiconductor substrate, wherein the isolation structure has a top surface extending to and coplanar with a second top surface of the semiconductor substrate, and the second top surface is lower than the first top surface; and forming a bit line contact layer on the second top surface of the semiconductor substrate and surrounded by the isolation structure.

In some embodiments, the manufacturing of the memory structure further includes before forming the first trench and the second trench in the semiconductor substrate, forming a first isolation layer and a second isolation layer on the semiconductor substrate in sequence.

In some embodiments, the manufacturing of the memory structure further includes after forming the first trench and the second trench in the semiconductor substrate, forming an outer oxide layer extending along the sidewall of the first trench and the sidewall of the second trench; and forming an inner oxide layer on the second isolation layer and the outer oxide layer, wherein the inner oxide layer has a first portion between a barrier layer and an upper gate electrode of each of the word line structures, and between the outer oxide layer and the upper gate electrode, and has a second portion on the upper gate electrode.

In some embodiments, the manufacturing of the memory structure further includes before forming the isolation structure in the first trench and the second trench, removing the second portion of the inner oxide layer and a portion of the outer oxide layer higher than a top surface of the upper gate electrode.

In some embodiments, a material of the second isolation layer comprises nitride, a material of the semiconductor substrate comprises silicon, and removing the second portion of the inner oxide layer and the portion of the outer oxide layer is performed by an oxide strip process having a high selectivity between oxide and nitride and between oxide and silicon.

In the aforementioned embodiments of the present disclosure, because the isolation structure of the memory structure is in contact with the sidewall of the first trench and the sidewall of the second trench, and the top surface of the isolation structure extends to and is coplanar with the second top surface of the semiconductor substrate, there is no void formed between the isolation structure and the semiconductor substrate. As a result, after the formation of the bit line contact layer, there is no portion of the bit line contact layer formed between the isolation structure and the semiconductor substrate, thereby preventing the leakage issue of current. Moreover, an additional etching process applied to prevent voids between a traditional isolation structure and the semiconductor substrate can be omitted, and therefore the trench expansion issue does not appear in the memory structure and the size of the memory structure is not limited.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a top view of a memory structure according to one embodiment of the present disclosure.

FIG. 2 is a cross-sectional view of the memory structure taken along line 2-2 shown in FIG. 1.

FIGS. 3 to 10 are cross-sectional views at intermediate stages of the manufacturing method of the memory structure of FIG. 2.

### DETAILED DESCRIPTION

The following disclosure provides many different embodiments, or examples, for implementing different features of the provided subject matter.

Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

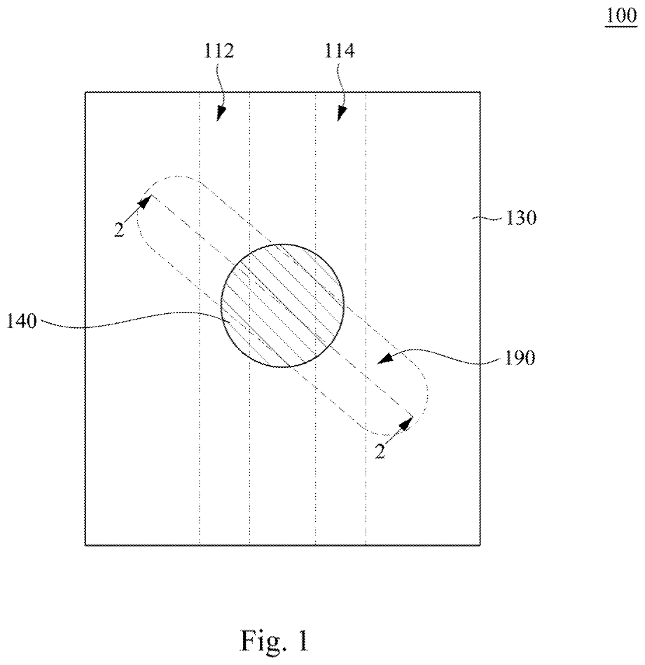

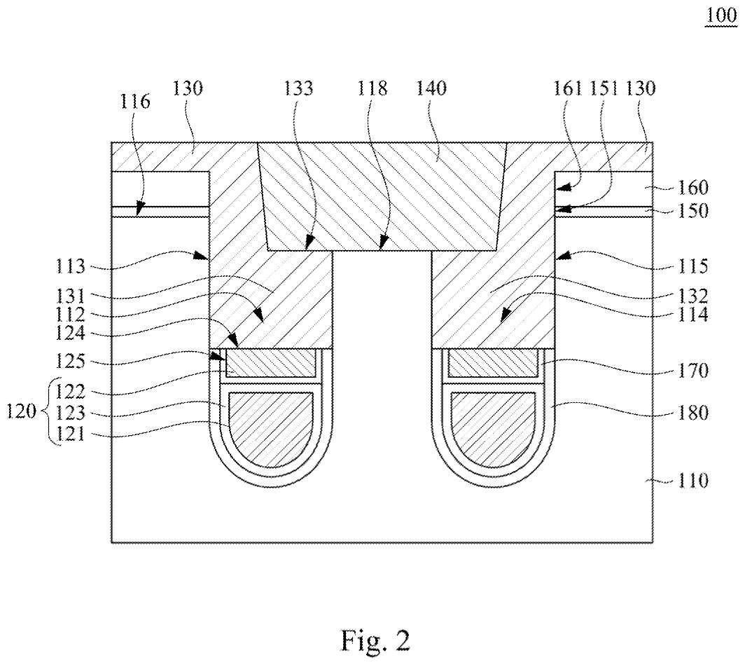

FIG. 1 is a top view of a memory structure 100 according to one embodiment of the present disclosure. FIG. 2 is a cross-sectional view of the memory structure 100 taken along line 2-2 shown in FIG. 1. As shown in FIG. 1 and FIG. 2, the memory structure 100 includes a semiconductor substrate 110, two word line structures 120, an isolation structure 130, and a bit line contact layer 140. The semiconductor substrate 110 has a first trench 112, a second trench 114, a first top surface 116, and a second top surface 118 that is between the first trench 112 and the second trench 114. The second top surface 118 is lower than the first top surface 116. One of the two word line structures 120 is located in a lower portion of the first trench 112, and the other word line structure 120 is located in a lower portion of the second trench 114. The isolation structure 130 is located in the first trench 112 and the second trench 114 and on the two word line structures 120. Furthermore, the isolation structure 130 is in contact with a sidewall 113 of the first trench 112, a sidewall 115 of the second trench 114, and extends onto the first top surface 116 of the semiconductor substrate 110.

The isolation structure 130 has a top surface 133 extending to and coplanar with the second top surface 118 of the semiconductor substrate 110. In addition, the isolation structure 130 is in contact with top surfaces of the two word line structures 120. The bit line contact layer 140 is located on the second top surface 118 of the semiconductor substrate 110 and surrounded by the isolation structure 130. In addition, the memory structure 100 further includes an active region 190 defined by a curved dotted line of FIG. 1.

Specifically, because the isolation structure 130 of the memory structure 100 is in contact with the sidewall 113 of the first trench 112 and the sidewall 115 of the second trench 114, and the top surface 133 of the isolation structure 130 extends to and is coplanar with the second top surface 118 of the semiconductor substrate 110, there is no void formed between the isolation structure 130 and the first trench 112 of the semiconductor substrate 110, and between the isolation structure 130 and the second trench 114 of the semiconductor substrate 110. As a result, there is no portion of the bit line contact layer 140 between the isolation structure 130 and the semiconductor substrate 110 after the formation of the bit line contact layer 140. Accordingly, the leakage issue of current induced by the aforesaid voids filled with a bit line contact layer can be prevented. Moreover, an additional dry etching and cleaning process applied to prevent the aforesaid voids is excluded in the fabrication process of the memory structure 100, and therefore the trench expansion issue limiting the size of the memory structure 100 does not appear.

Moreover, the memory structure 100 further includes a first isolation layer 150 and a second isolation layer 160. The first isolation layer 150 is on the first top surface 116 of the semiconductor substrate 110. The second isolation layer 160 is on the first isolation layer 150. In addition, the first isolation layer 150 and the second isolation layer 160 have an inner sidewall 151 and an inner sidewall 161, respectively, in which the inner sidewalls 151 and 161 are in contact with the isolation structure 130. Furthermore, the inner sidewall 151 of the first isolation layer 150 and the inner sidewall 161 of the second isolation layer 160 are perpendicular to the first top surface 116 of the semiconductor substrate 110. The configuration of the memory structure 100 does not suffer from the trench expansion issue induced by an additional dry etching process. Hence, the size of the memory structure 100 can be smaller than a traditional memory structure.

In this embodiment, the bit line contact layer 140 has no portion between the first isolation layer 150 and the isolation structure 130, and between the second isolation layer 160 and the isolation structure 130. The bit line contact layer 140 has no portion below the second top surface 118 of the semiconductor substrate 110. In addition, the bit line contact layer 140 has a trapezoid profile in cross-section. Compared with prior art, the leakage issue of current does not appear in the memory structure 100 because there is no unwanted portion of the bit line contact layer 140 formed between the first isolation layer 150 and the isolation structure 130, between the second isolation layer 160 and the isolation structure 130, and below the second top surface 118 of the semiconductor substrate 110.

In addition, each of the two word line structures 120 further includes a lower gate electrode 121, an upper gate electrode 122, and a barrier layer 123. The upper gate electrode 122 overlaps the lower gate electrode 121 and has a top surface 124 in contact with the isolation structure 130. The barrier layer 123 surrounding the lower gate electrode 121 and has a portion between the upper gate electrode 122 and the lower gate electrode 121. A material of the lower gate electrode 121 is different from a material of the upper gate electrode 122. For example, the material of the lower gate electrode 121 may include tungsten, and the material of the upper gate electrode 122 may include polysilicon, but the present disclosure is not limited in this regard. Furthermore, the material of the upper gate electrode 122 is the same as a material of the bit line contact layer 140. A material of the barrier layer 123 may include titanium nitride. In this embodiment, the memory structure 100 has the word line structure 120 including the lower gate electrode 121, the upper gate electrode 122, and the barrier layer 123, and thus the memory structure 100 has the buried dual work function gate electrode. As a result of such a design, the buried dual work function gate electrode can prevent the gate-induced drain leakage issue (GIDL), which is a leakage mechanism in metal-oxide-semiconductor field-effect transistors due to large field effect in the drain junction, and has quite an impact on the reliability of semiconductor devices. The word line structure 120 including the lower gate electrode 121 that is made of tungsten having higher work function, and the upper gate electrode 122 made of polysilicon having lower work function are designed to improve the GIDL issue.

In this embodiment, the memory structure 100 further includes an outer oxide layer 170 and an inner oxide layer 180. The outer oxide layer 170 is located between the upper gate electrode 122 and the barrier layer 123, and extends to the isolation structure 130 along a sidewall 125 of the upper gate electrode 122.

The inner oxide layer 180 is located between the outer oxide layer 170 and the sidewall of the first trench 112, between the outer oxide layer 170 and the sidewall of the second trench 114, between the barrier layer 123 and the sidewall of the first trench 112, and between the barrier layer 123 and the sidewall of the second trench 114. In some embodiments, a material of the outer oxide layer 170 and a material of the inner oxide layer 180 may include silicon dioxide.

Moreover, the isolation structure 130 has a first portion 131 in the first trench 112 and a second portion 132 in the second trench 114. A width of the first portion 131 is the same as a width of the first trench 112, and a width of the second portion 132 is the same as a width of the second trench 114. The outer oxide layer 170 and the inner oxide layer 180 have no portion between a sidewall of the first portion 131 of the isolation structure 130 and the sidewall 113 of the first trench 112, and between a sidewall of the second portion 132 of the isolation structure 130 and the sidewall 115 of the second trench 114.

In the following description, the manufacturing method of the memory structure 100 will be explained. It is to be noted that the connection relationships, the materials, and the advantages of the elements described above will not be repeated in the following description.

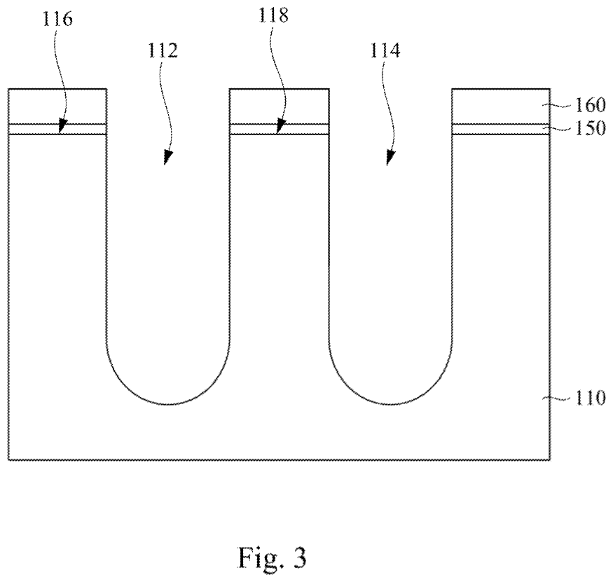

FIGS. 3 to 10 are cross-sectional views at intermediate stages of the manufacturing method of the memory structure 100 of FIG. 2. As shown in FIG. 3, the manufacturing method of the memory structure 100 includes forming the first isolation layer 150 and the second isolation layer 160 on the semiconductor substrate 110 in sequence, and forming the first trench 112 and the second trench 114 in the semiconductor substrate 110.

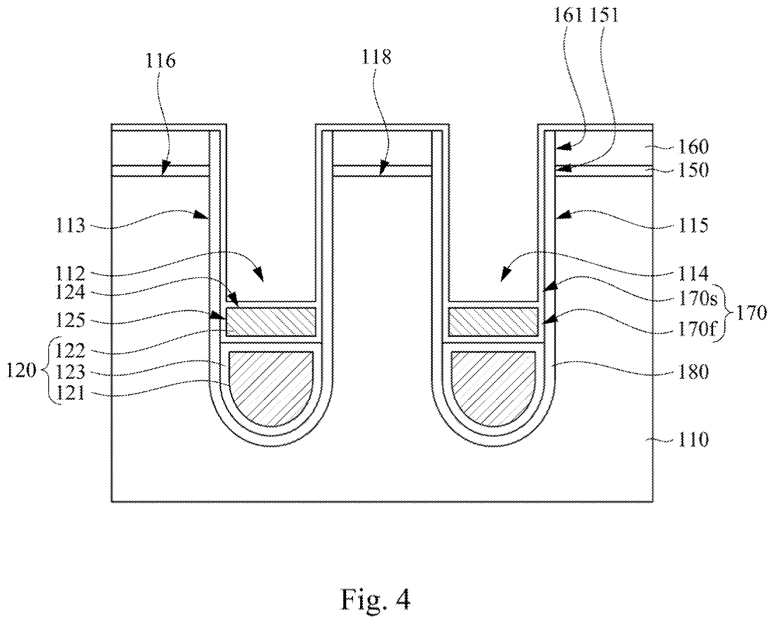

As shown in FIG. 4, thereafter, the two word line structures 120 are formed respectively in the first trench 112 and the second trench 114, and the inner oxide layer 180 is formed to extend along the sidewall 113 of the first trench 112 and the sidewall 115 of the second trench 114. Furthermore, the outer oxide layer 170 is formed on the second isolation layer 160 and the inner oxide layer 180. In some embodiments, the inner oxide layer 180 is formed in the first trench 112 and extends from the sidewall 113 to the inner sidewall 151 of the first isolation layer 150 and the inner sidewall 161 of the second isolation layer 160. Simultaneously, the inner oxide layer 180 is formed in the second trench 114 and extends from the sidewall 115 to the inner sidewall 151 of the first isolation layer 150 and the inner sidewall 161 of the second isolation layer 160. Thereafter, each of the lower gate electrodes 121 respectively surrounded by the barrier layers 123 is formed at the lower portion of one of the first trench 112 and the second trench 114. Subsequently, the outer oxide layer 170 and the upper gate electrode 122 are formed on the barrier layer 123 of each of the word line structures 120, in which the outer oxide layer 170 has a first portion 170f between the barrier layer 123 and the upper gate electrode 122 of each of the word line structures 120, and between the inner oxide layer 180 in each of the first trench 112 and the second trench 114 and the upper gate electrode 122 of each of the word line structures 120, and has a second portion 170s on the second isolation layer 160, the inner oxide layer 180 in each of the first trench 112 and the second trench 114, and the upper gate electrode 122 of each of the word line structures 120. In some embodiments, the inner oxide layer 180 may be formed by atomic layer deposition and oxidized by in-situ steam generation having rapid thermal process. The outer oxide layer 170 may be formed by atomic layer deposition. The present disclosure is not limited in this regard.

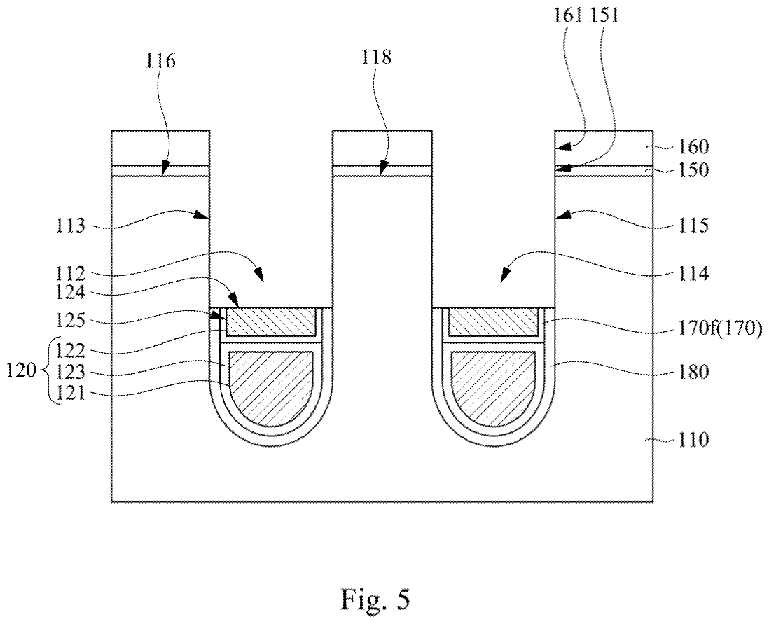

As shown in FIG. 5, thereafter, the second portion 170s of the outer oxide layer 170 and a portion of the inner oxide layer 180 that are higher than a top surface 124 of the upper gate electrode 122 are removed. In some embodiments, a material of the second isolation layer 160 comprises nitride, a material of the semiconductor substrate 110 comprises silicon. Removing the second portion 170s of the outer oxide layer 170 and the portion of the inner oxide layer 180 is performed by an oxide strip process having a high selectivity between oxide and nitride and between oxide and silicon. Accordingly, the inner sidewall 151 of the first isolation layer 150 and the inner sidewall 161 of the second isolation layer 160 are perpendicular to the first top surface 116 of the semiconductor substrate 110. Therefore, by applying the oxide strip process rather than the additional dry etching and cleaning process during fabrication the memory structure 100, the trench expansion issue can be avoided. Therefore, the size of the memory structure 100 is not limited.

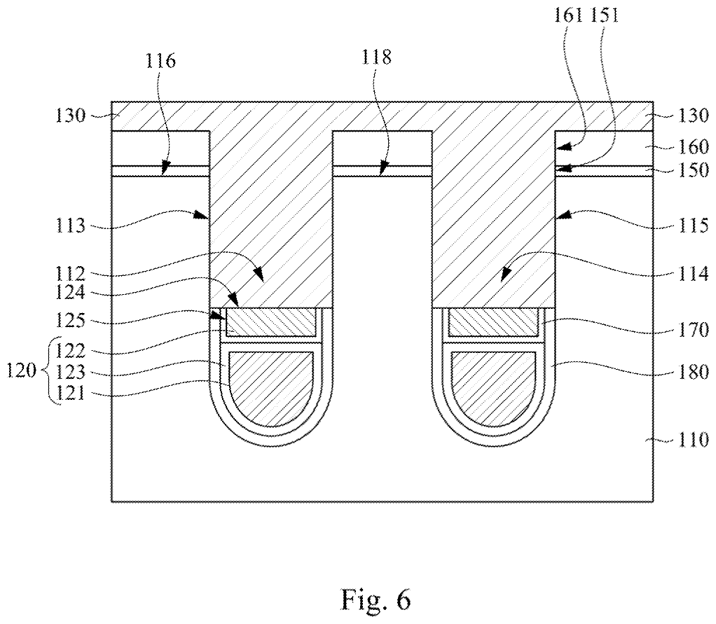

Referring to FIG. 6, after the structure of FIG. 5 is formed, the isolation structure 130 is formed in the first trench 112 and the second trench 114 and on the two word line structures 120, such that the isolation structure 130 is in contact with the sidewall 113 of the first trench 112 and the sidewall 115 of the second trench 114, and extends onto the first top surface 116 of the semiconductor substrate 110. In some embodiments, the isolation structure 130 is in contact with top surfaces of the two word line structures 120 (i.e., the top surface 124 of the upper gate electrode 122 shown in FIG. 5).

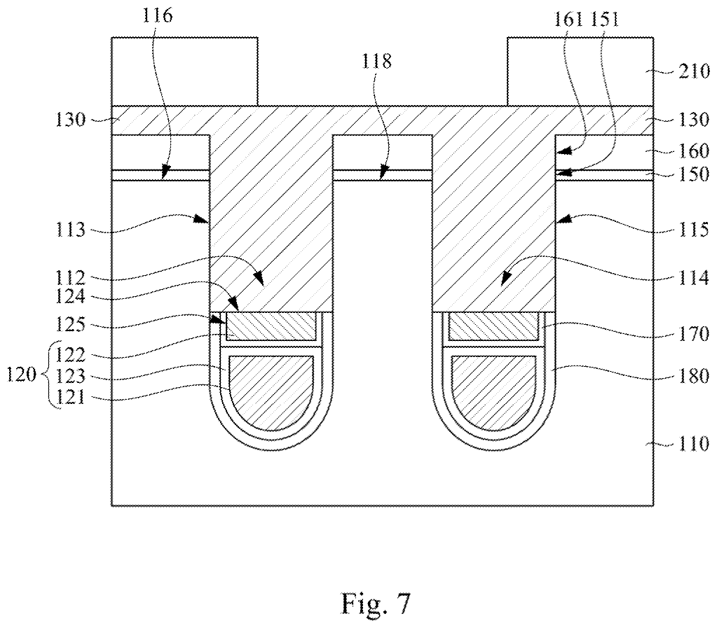

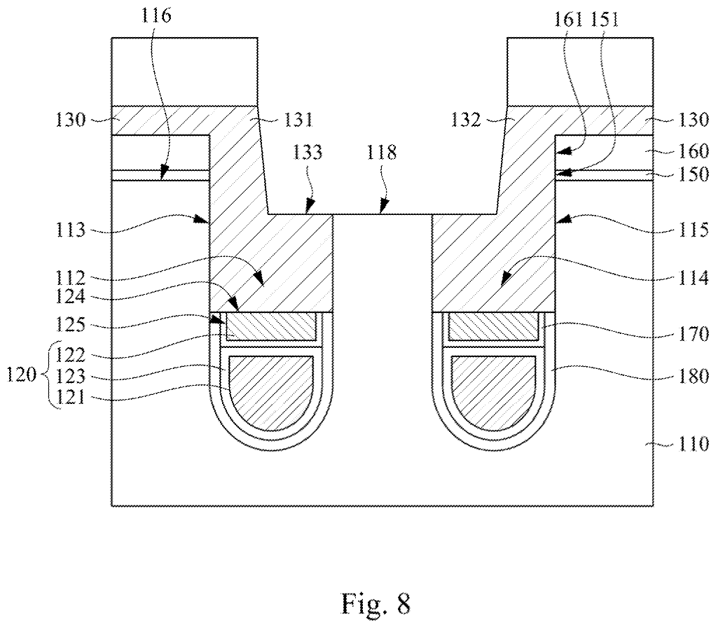

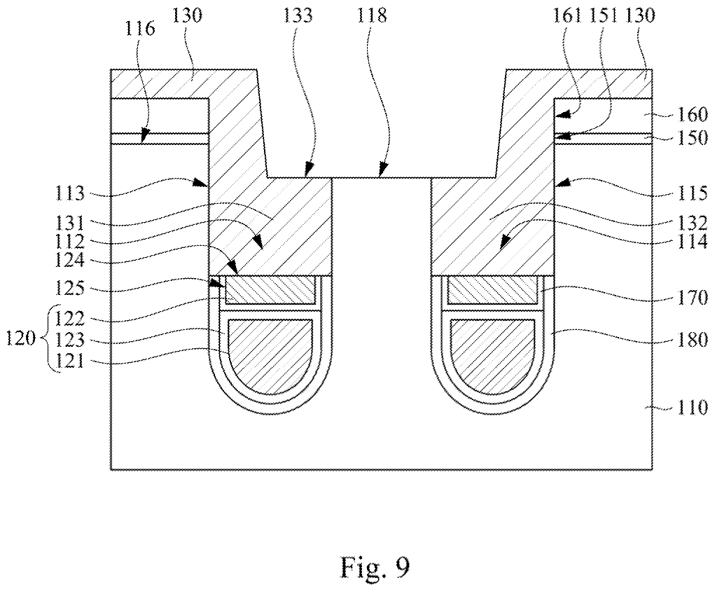

As shown in FIGS. 7 and 8, thereafter, a hard mask 210 is formed on top of the isolation structure 130, wherein the hard mask 210 has an opening having a normal projection overlapping a portion of the first trench 112, a portion of the second trench 114, and the second top surface 118 of the semiconductor substrate 110. Subsequently, a portion of the isolation structure 130 under the opening of the hard mask 210, the first isolation layer 150 and the second isolation layer 160 upon the second top surface 118, and a portion of the semiconductor substrate 110 underneath the second top surface 118 are removed by a dry etching process and a cleaning process. As a result, the isolation structure 130 has a top surface 133 extending to and coplanar with the second top surface 118 of the semiconductor substrate 110. After the dry etching process, the hard mask 210 can be removed to form the structure of FIG. 9. As shown in FIG. 9, the outer oxide layer 170 and the inner oxide layer 180 have no portion between the sidewall of the first portion 131 of the isolation structure 130 and the sidewall 113 of the first trench 112, and between the sidewall of the second portion 132 of the isolation structure 130 and the sidewall 115 of the second trench 114. Therefore, the leakage issue of current induced by oxide loss caused by traditional dry etching and cleaning process is avoided.

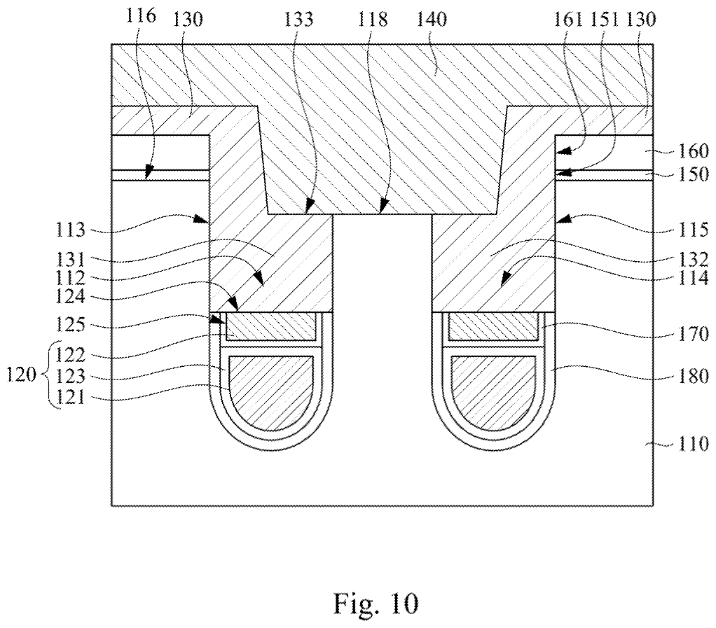

As shown in FIG. 10, after removing the hard mask 210 of FIG. 8, the bit line contact layer 140 is formed on the second top surface 118 of the semiconductor substrate 110 and the isolation structure 130. Since there is no void formed between the isolation structure 130 and the semiconductor substrate 110, there is no portion of the bit line contact layer 140 formed between the isolation structure 130 and the semiconductor substrate 110 after the formation of the bit line contact layer 140. Subsequently, referring to FIG. 2, an upper portion of the bit line contact layer 140 is removed. The bit line contact layer 140 has no portion between the first isolation layer 150 and the isolation structure 130, and between the second isolation layer 160 and the isolation structure 130. The isolation structure 130 has the top surface 133 extending to and coplanar with the second top surface 118 of the semiconductor substrate 110. The leakage issue of current due to unwanted portion of the bit line contact layer 140 in the memory structure 100 is prevented.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory structure, comprising:
a semiconductor substrate having a first trench, a second trench, a first top surface, a second top surface between the first trench and the second trench, wherein the second top surface is lower than the first top surface;
two word line structures, wherein one of the two word line structures is located in a lower portion of the first trench, and the other word line structure is located in a lower portion of the second trench;
an isolation structure located in the first trench and the second trench and on the two word line structures, in contact with a sidewall of the first trench and a sidewall of the second trench, and extending onto the first top surface of the semiconductor substrate, wherein the isolation structure has a top surface extending to and coplanar with the second top surface of the semiconductor substrate; and
a bit line contact layer on the second top surface of the semiconductor substrate and surrounded by the isolation structure.

2. The memory structure of claim 1, wherein the isolation structure is in contact with top surfaces of the two word line structures.

3. The memory structure of claim 1, further comprising:
a first isolation layer on the first top surface of the semiconductor substrate; and
a second isolation layer on the first isolation layer, wherein each of the first isolation layer and the second isolation layer has an inner sidewall in contact with the isolation structure.

4. The memory structure of claim 3, wherein the inner sidewall of the first isolation layer and the inner sidewall of the second isolation layer are perpendicular to the first top surface of the semiconductor substrate.

5. The memory structure of claim 3, wherein the bit line contact layer has no portion between the second isolation layer and the isolation structure.

6. The memory structure of claim 1, wherein the bit line contact layer has no portion below the second top surface of the semiconductor substrate.

7. The memory structure of claim 1, wherein the bit line contact layer has a trapezoid profile in cross-section.

8. The memory structure of claim 1, wherein each of the two word line structures further comprises:
a lower gate electrode;
an upper gate electrode overlapping the lower gate electrode and has a top surface in contact with the isolation structure; and
a barrier layer surrounding the lower gate electrode and has a portion between the upper gate electrode and the lower gate electrode.

9. The memory structure of claim 8, wherein a material of the lower gate electrode is different from a material of the upper gate electrode.

10. The memory structure of claim 9, wherein the material of the lower gate electrode comprises tungsten, and the material of the upper gate electrode comprises polysilicon.

11. The memory structure of claim 8, wherein the upper gate electrode and the bit line contact layer comprise a same material.

12. The memory structure of claim 8, wherein a material of the barrier layer comprises titanium nitride.

13. The memory structure of claim 8, further comprising:
an inner oxide layer located between the upper gate electrode and the barrier layer, and extending to the isolation structure along a sidewall of the upper gate electrode.

14. The memory structure of claim 13, further comprising:
an outer oxide layer located between the inner oxide layer and the sidewall of one of the first trench and the second trench, and between the barrier layer and the sidewall of one of the first and second trenches.

15. The memory structure of claim 1, wherein the isolation structure has a first portion in the first trench and a second portion in the second trench, a width of the first portion is the same as a width of the first trench, and a width of the second portion is the same as a width of the second trench.

16. A manufacturing method of a memory structure, comprising:
forming a first trench and a second trench in a semiconductor substrate;
forming two word line structures respectively in the first trench and the second trench;
forming an isolation structure in the first trench and the second trench and on the two word line structures, wherein the isolation structure is in contact with a sidewall of the first trench and a sidewall of the second trench, and extends onto a first top surface of the semiconductor substrate;
removing a portion of the isolation structure and a portion of the semiconductor substrate, wherein the isolation structure has a top surface extending to and coplanar with a second top surface of the semiconductor substrate, and the second top surface is lower than the first top surface; and
forming a bit line contact layer on the second top surface of the semiconductor substrate and surrounded by the isolation structure.

17. The manufacturing method of the memory structure of claim 16, further comprising:
before forming the first trench and the second trench in the semiconductor substrate, forming a first isolation layer and a second isolation layer on the semiconductor substrate in sequence.

18. The manufacturing method of the memory structure of claim 17, further comprising:
after forming the first trench and the second trench in the semiconductor substrate, forming an inner oxide layer extending along the sidewall of the first trench and the sidewall of the second trench; and
forming an outer oxide layer on the second isolation layer and the inner oxide layer, wherein the outer oxide layer has a first portion between a barrier layer and an upper gate electrode of each of the word line structures, and between the inner oxide layer and the upper gate electrode, and has a second portion on the upper gate electrode.

19. The manufacturing method of the memory structure of claim 18, further comprising:
before forming the isolation structure in the first trench and the second trench, removing the second portion of the outer oxide layer and a portion of the inner oxide layer higher than a top surface of the upper gate electrode.

20. The manufacturing method of the memory structure of claim 19, wherein a material of the second isolation layer comprises nitride, a material of the semiconductor substrate comprises silicon, and removing the second portion of the outer oxide layer and the portion of the inner oxide layer is performed by an oxide strip process having a high selectivity between oxide and nitride and between oxide and silicon.
